(19) United States
(12) Patent Application Publication
(10) Pub. No.: US 2020/0279959 A1
(43) Pub. Date: Sep. 3, 2020

(54) ENERGY CONVERSION DEVICE HAVING A SUPERLATTICE ABSORPTION LAYER AND METHOD

(71) Applicant: KING ABDULLAH UNIVERSITY OF SCIENCE AND TECHNOLOGY, Thuwal (SA)

(72) Inventors: Daisuke IIDA, Thuwal (SA); Kazuhiro OHKAWA, Thuwal (SA)

(21) Appl. No.: 16/765,449

(22) PCT Filed: Nov. 15, 2018
(86) PCT No.: PCT/IB2018/059011

§ 371 Date: May 19, 2020

Related U.S. Application Data
(60) Provisional application No. 62/633,690, filed on Feb. 22, 2018.
(60) Provisional application No. 62/597,565, filed on Dec. 12, 2017.

(51) Int. Cl. H01L 31/0352; H01L 31/0336; H01L 31/18; C25B 1/00; C25B 1/04

(52) U.S. Cl. CPC H01L 31/035236; H01L 31/0336; C25B 1/04; C25B 1/003; H01L 31/18

(57) ABSTRACT

An energy conversion device includes a substrate, a first doped semiconductor layer arranged on the substrate, and an absorption layer arranged on the first doped semiconductor layer. The absorption layer includes a superlattice having a III-nitride layer adjacent to a II-oxide layer.

### CROSS-REFERENCE TO RELATED APPLICATIONS

This application claims priority to U.S. Provisional Patent Application No. 62/597,565, filed on Dec. 12, 2017, entitled “PHOTOELECTRIC ENERGY CONVERSIONS DEVICES WITH III-NITRIDE- AND II-OXIDE-BASED TYPE-II SUPERLATTICES STRUCTURE,” and U.S. Provisional Patent Application No. 62/633,690, filed on Feb. 22, 2018, entitled “ENERGY CONVERSION DEVICE HAVING A SUPERLATTICE ABSORPTION LAYER AND METHOD,” the disclosures of which are incorporated herein by reference in their entirety.

### BACKGROUND

### Technical Field

Embodiments of the disclosed subject matter generally relate to an energy conversion device having a superlattice absorption layer and method for forming an energy conversion device having a superlattice absorption layer.

### Discussion Of The Background

The desire to reduce pollution from conventional fossil fuel sources has led to an increasing reliance on so-called green energy conversion devices, such as solar cells that convert solar energy to electric energy and photocatalysts used for water splitting. Solar cells typically employ compound materials based on silicon (Si), gallium phosphide (GaP), and gallium arsenide (GaAs). Solar cells based on these compound materials, however, are close to reaching their theoretical limit in terms of energy conversion efficiency. Further, these materials provide a limited set of bandgaps, which define the wavelength of light that is converted into energy. Accordingly, increasing adoption of energy conversion devices, such as solar cells and photocatalysts, will require the use of new materials to better compete with fossil fuel sources.

Thus, it would be desirable to provide for an energy conversion device having improved energy conversion efficiency compared to energy conversion devices employing compound materials based on silicon, gallium phosphide, and gallium arsenide, as well as providing for more ability to define the bandgap of the energy conversion device.

### SUMMARY

According to an embodiment, there is an energy conversion device, which includes a substrate, a first doped semiconductor layer arranged on the substrate, and an absorption layer arranged on the first doped semiconductor layer. The absorption layer comprises a superlattice comprising a Ill-nitride layer adjacent to a II-oxide layer.

According to another embodiment, there is a method for forming an energy conversion device. A first doped semiconductor layer is formed on a substrate. An absorption layer is formed on the first doped semiconductor layer. The absorption layer comprises a superlattice comprising a III-nitride layer adjacent to a II-oxide layer.

According to a further embodiment, there is a method for forming an energy conversion device, a first doped semiconductor layer is formed on a substrate. An absorption layer is formed on the first doped semiconductor layer by forming a first portion of the absorption layer by controlling a concentration of one of a group III element in a III-nitride and a group II element in a II-oxide and forming a second portion of the absorption layer by controlling a concentration of the other one of a group III element in a III-nitride and a group II element in a II-oxide. The concentration of the group III element in the III-nitride and the concentration of the group II element in the II-oxide define a bandgap of the absorption layer.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1A is a schematic diagram of an energy conversion device according to an embodiment;

FIG. 1B is a schematic diagram of an energy conversion device according to an embodiment;

FIG. 2 is a graph of energy bandgaps of a number of materials according an embodiment;

FIG. 3 is a chart of the energy bandgap of a number of different superlattices according to an embodiment;

FIG. 4A is a flowchart of a method for forming an energy conversion device according to an embodiment;

FIG. 4B is a flowchart of a method for forming an energy conversion device according to an embodiment;

FIG. 5A is a schematic diagram of an energy conversion device according to an embodiment;

FIG. 5B is a schematic diagram of an energy conversion device according to an embodiment;

FIG. 6A is a flowchart of a method for forming an energy conversion device according to an embodiment; and

FIG. 6B is a flowchart of a method for forming an energy conversion device according to an embodiment.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of energy conversion devices having a superlattice absorption layer.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

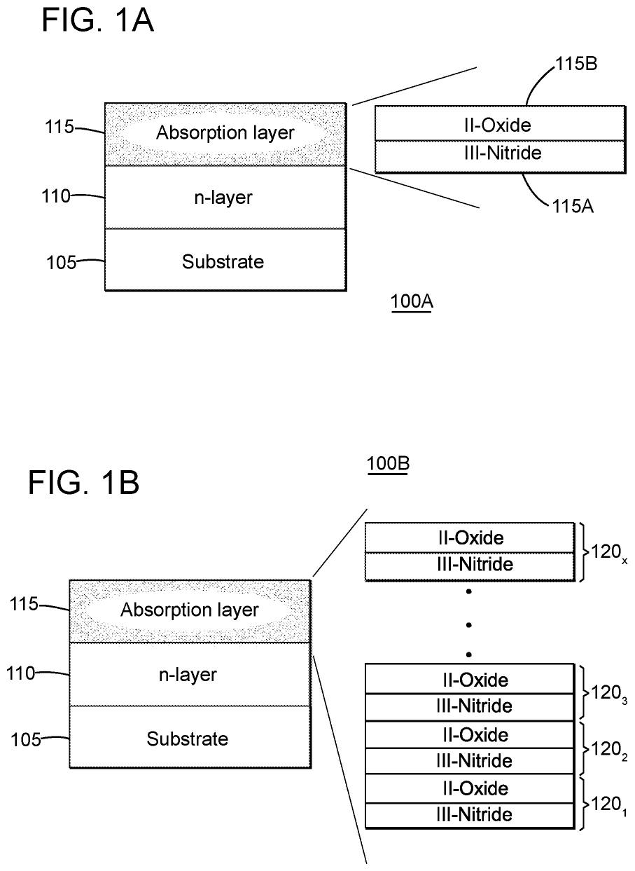

FIG. 1A illustrates an energy conversion device 100A according to an embodiment. The energy conversion device 100A includes a substrate 105 and a first doped semiconductor layer 110 arranged on the substrate 105. In an embodiment, the first doped semiconductor layer 110 is a n-type layer. The energy conversion device 100A also includes an absorption layer 115 arranged on the first doped semiconductor layer 110. The absorption layer 115 includes a superlattice comprising a III-nitride layer 115A adjacent to a II-oxide layer 115B. Although FIG. 1A illustrates the III-nitride layer 115A being adjacent to the first doped semiconductor layer 110, the II-oxide layer 1158 can be adjacent to the first doped semiconductor layer 110.

The first doped semiconductor layer 110 can be, for example, between 1 and 10 μM thick, more preferably between 3 and 5 μM thick, and in one embodiment is 3 μM thick. The first semiconductor layer 110 can be, for example, silicon-doped n-type gallium nitride layer grown on a substrate with a 20 nm thick low-temperature gallium nitride buffer layer. The silicon concentration of the n-type gallium nitride layer can be, for example, between 1×10¹⁷ cm⁻³ and 1×10¹⁹ cm^{×3}, and in one embodiment can be 3×10¹⁸ cm⁻³. The III-nitride layer 115A and the II-oxide layer 115B can both be, for example, between 0.5 and 10 nm thick, more preferably between 1 and 3 nm, and in one embodiment can be 2 nm thick. The substrate 105 can be, for example, sapphire, silicon carbide, silicon, gallium oxide (Ga₂O₃), zinc oxide, gallium nitride, etc.

The superlattice can be a type-I or type-II superlattice, both of which are particularly useful because these superlattices provide reduced strain to the adjacent layers, i.e., the first doped semiconductor layer 110 in this example, and thus provides improved device performance compared to an absorption layer having a large lattice mismatch with the adjacent layers. Further, II-oxide and III-nitride materials are considered to be particularly tough materials that are able to be used in a large range of applications while minimizing device degradation due to environmental factors.

The first doped semiconductor layer 110 can be comprised of a III-nitride or II-oxide material, however, the first doped semiconductor layer 110 should have a bandgap that is larger than the bandgap of the absorption layer 115 so that the energy can pass through the first doped semiconductor layer 110 to be absorbed by the absorption layer 115.

The energy conversion device 100A in this example is a photocatalyst that can be used for water splitting, i.e., the generation of hydrogen by splitting converting water into hydrogen and oxygen.

The absorption layer 115 can have more than just one set of II-oxide and III-nitride layers. Specifically, as illustrated in FIG. 1B, the absorption layer 115 of the energy conversion device 100B can include a plurality of sets 120₁-120ₓ of II-oxide and III-nitride layers. The II-oxide layers should have the same material and can have the same or different compositions of this same material. Likewise, the III-nitride layers should have the same material and can have the same or different compositions of this same material. In an embodiment, the number of sets of II-oxide and III-nitride layers can be, for example, greater than ten sets. Although FIG. 1B illustrates a III-nitride layer adjacent to the first doped semiconductor layer 110, a II-oxide layer can be adjacent to the first doped semiconductor layer 110.

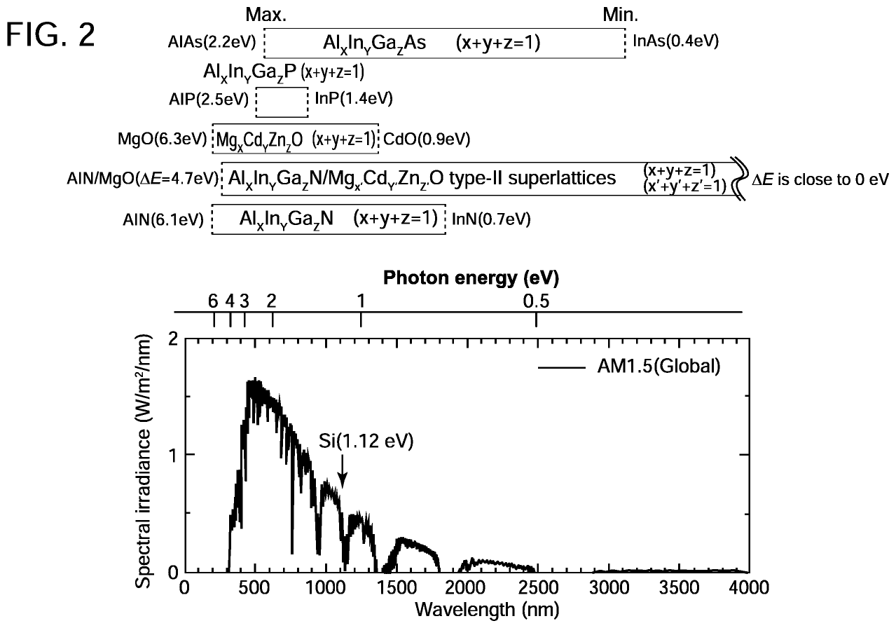

The composition of materials of the II-oxide and III-nitride layers define the bandgap of the absorption layer, and thus the bandgap of the device 100A or 100B. Specifically, as illustrated in FIG. 2, a type-II superlattice of II-oxide and III-nitride layers can have a bandgap ranging between 4.7 eV (where the superlattice is comprised of aluminum nitride and magnesium oxide layers) and approximately 0 eV, depending upon the composition of the II-oxide and III-nitride layers.

The bandgap of an absorption layer comprised of II-oxide and III-nitride layers in a type-II superlattice can be defined by adjusting the values of x, y, and z for the III-nitride layer of AlₓIn_{y}Ga_{z}N and adjusting the values of x′, y′, and z′ for the II-oxide layer of Mg_{x′}Cd_{y′}Zn_{z′}O between 4.7 eV and approximately 0 eV. As illustrated in FIG. 2, this range of possible bandgaps is much larger than what can be achieved using a gallium arsenic-based absorption layer (AlₓIn_{y}Ga_{z}As in the figure), a gallium phosphide-based absorption layer (AlₓIn_{y}Ga_{z}P in the figure), a II-oxide absorption layer (MgₓCd_{y}Zn_{z}O in the figure), or a III-nitride absorption layer (AlₓIn_{y}Ga_{z}N in the figure). It will be recognized that x, y, and z can take any value between 0 and 1 and that x+y+z=1. Thus, the disclosed absorption layer provides the ability to select the desired bandgap of the device within a wide range of bandgaps, compared to conventional devices that can provide a more limited bandgap selection.

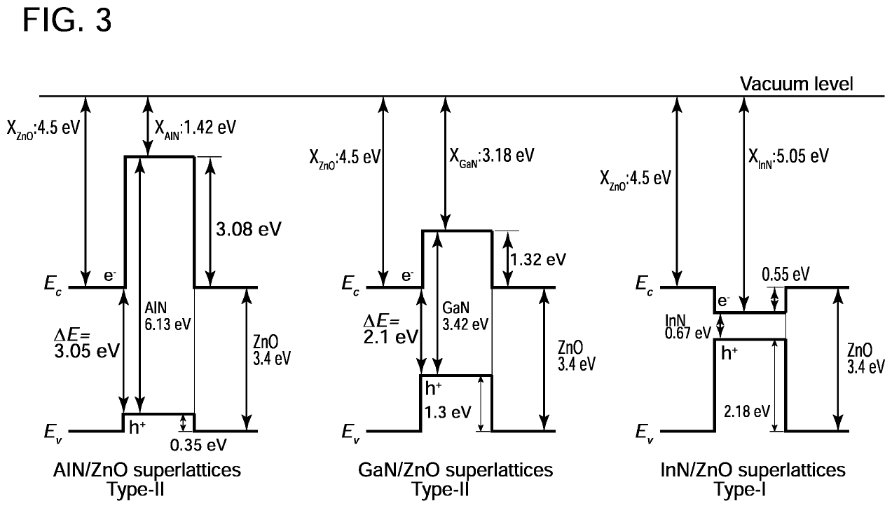

Defining the bandgap by controlling the composition of the II-oxide and III-nitride layers is illustrated in FIG. 3. As illustrated in FIG. 3, the bandgap ΔE of a type-II superlattice is the difference between the conduction band E_{c} of one layer and the valence band Eᵥ of the other layer. Thus, as illustrated, the bandgap ΔE of a type-II superlattice of aluminum nitride (i.e., a III-nitride) and zinc oxide (i.e., a II-oxide) is approximately 3.05 eV, which is the difference between the conduction band E_{c} of the zinc oxide layer (which itself has a bandgap of 3.4 eV) and the valence band Eᵥ of the aluminum nitride layer (which itself has a bandgap of 6.13 eV).

Similarly, as illustrated, the bandgap ΔE of a type-II superlattice of gallium nitride (i.e., a III-nitride) and zinc oxide (i.e., a II-oxide) is approximately 2.1 eV, which is the difference between the conduction band E_{c} of the zinc oxide layer (which itself has a bandgap of 3.4 eV) and the valence band Eᵥ of the gallium nitride layer (which itself has a bandgap of 3.42 eV). Thus, as will be appreciated from FIG. 3, the bandgap of an absorption layer having a type-II superlattice of II-oxide and III-nitride layers is less than the bandgap of the II-oxide and III-nitride layers.

Although examples have been described in connection with an absorption layer including a type-II superlattice, the absorption layer can also include a type-I superlattice of a II-oxide layer and III-nitride layer. An example of this is illustrated in FIG. 3 in which the II-oxide layer is zinc oxide and the III-nitride layer is indium nitride. The bandgap of a type-I superlattice is defined by the bandgap ΔE (i.e., the difference between the conduction band E_{c} and the valence band Eᵥ) of a single layer, which in the illustrated example is the indium nitride layer having a bandgap of 0.67 eV. A type-I superlattice can be employed to absorb energy within the visible region of light, whereas the narrow bandgap of some type-II superlattices is not good within the visible region because there is too much energy loss. Thus, the type-II superlattice is particularly useful within the infrared light range. Furthermore, the disclosed type-II superlattice can be employed to absorb energy within the visible light range because the bandgap of the disclosed type-II superlattice can be defined between, for example, 0 and 4.7 eV by adjusting the material composition of the II-oxide and/or III-nitride layers in the manner disclosed.

It will be recognized that reference to the bandgap of the absorption layer refers to the bandgap at the interface between a III-nitride and II-oxide layer. Thus, one will appreciate that an absorption layer can include a III-nitride layer or layers having a first bandgap, a II-oxide layer or layers having a second bandgap, and the interface between a pair of II-oxide and III-nitride layer having a third bandgap. For a type-II superlattice, the third bandgap is defined by the difference between the valence band of one of the II-oxide and III-nitride layers and the conduction band of the other one of the III-nitride and II-oxide layers. For a type-I superlattice, the third bandgap is equal to the bandgap of one of the II-oxide and III-nitride layers.

Further, it will be recognized that the interface between a III-nitride and II-oxide layer is where energy is absorbed, i.e., where the electron-hole pairs are created, and thus the amount of energy absorbed by the absorption layer depends upon the area of the interface. Accordingly, the amount of absorbed energy will increase as the number of sets of II-oxide and III-nitride layers is increased. Thus, the decision of the number of sets of II-oxide and III-nitride layers to implement in an absorption layer will depend upon the desired amount of energy to be absorbed by the particular device.

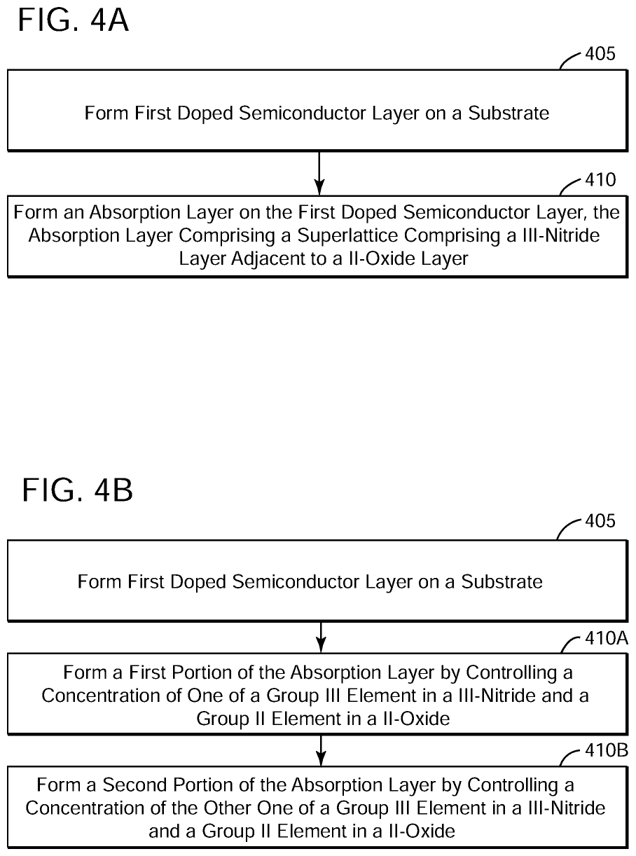

Flowcharts of methods of making the energy conversion device of FIGS. 1A and 1B are illustrated in FIGS. 4A and 4B. Initially, a first doped semiconductor layer 110 is formed on a substrate 105 (step 405). An absorption layer 115, comprising a superlattice of a III-nitride layer adjacent to a II-oxide layer, is then formed on the first doped semiconductor layer 110 (step 410).

As discussed above, the bandgap of the superlattice can be defined by controlling the composition of the II-oxide and III-nitride layers. Thus, as illustrated in the flowchart of FIG. 4B, the formation of the absorption layer can involve forming the II-oxide and III-nitride layers using particular compositions. Specifically, a first portion of the absorption layer 115 can be formed by controlling a concentration of one of a group III element in a III-nitride and a group II element in a II-oxide (step 410A) and a second portion of the absorption layer 115 can be formed by controlling the concentration of the other one of a group III element in a III-nitride layer and a group II element in a II-oxide layer (step 410B). The concentrations of these layers are defined by the values of x, y, and z for the III-nitride layer of AlₓIn_{y}Ga_{z}N and the values of x′, y′, and z′ for the II-oxide layer of Mg_{x′}Cd_{y′}Zn_{z′}O, wherein x+y+z=1 and x′+y′+z′=1.

The methods of FIGS. 4A and 4B can be performed using any number of techniques, including chemical vapor deposition, metal-organic vapor-phase epitaxy, etc.

Although the flowcharts of FIGS. 4A and 4B describe forming a superlattice of a single II-oxide layer and a single III-nitride layer, as discussed above, an energy conversion device 100A or 100B can include more than one set of these layers. In the case of more than one set of these layers, the method of FIG. 4A would involve forming these sets of layers. Similarly, in the case of more than one set of these layers, the method of FIG. 4B would include steps 410A and 410B repeated for each set of layers.

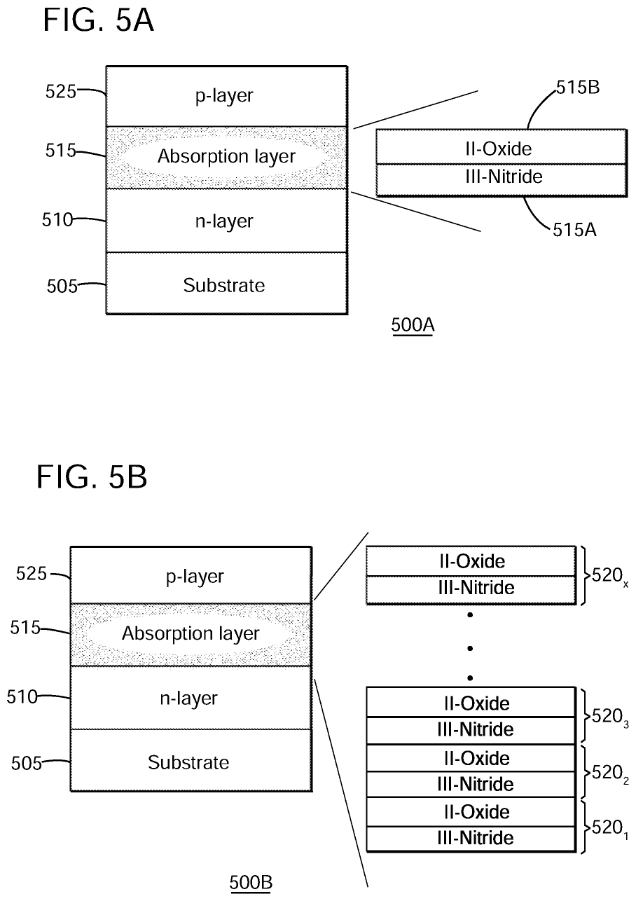

The discussion above describes a photocatalyst including an absorption layer comprising a superlattice of II-oxide and III-nitride layers. Such an absorption layer can also be employed for a solar cell, examples of which are illustrated in FIGS. 5A and 5B.

The energy conversion device 500A of FIG. 5A includes a substrate 505 and a first doped semiconductor layer 510 arranged on the substrate 505. In the illustrated embodiment, the first doped semiconductor layer 510 is a n-type layer. The substrate 505 can be, for example, sapphire, silicon carbide, silicon, gallium oxide (Ga₂O₃), zinc oxide, gallium nitride, etc. The first doped semiconductor layer 510 can be, for example, between 1 and 10 μM thick, more preferably between 3 and 5 μM thick, and in one embodiment is 3 μM thick. The first semiconductor layer 510 can be, for example, silicon-doped n-type gallium nitride layer grown on a substrate with a 20 nm thick low-temperature gallium nitride buffer layer. The silicon concentration of the n-type gallium nitride layer can be, for example, between 1×10¹⁷ cm⁻³ and 1×10¹⁹ cm⁻³, and in one embodiment can be 3×10¹⁸ cm⁻³.

The energy conversion device 500A also includes an absorption layer 515 arranged on the first doped semiconductor layer 510. The absorption layer 515 includes a superlattice comprising a III-nitride layer 515A adjacent to a II-oxide layer 515B. The III-nitride layer 515A and the II-oxide layer 515B can both be, for example, between 0.5 and 10 nm thick, more preferably between 1 and 3 nm, and in one embodiment can be 2 nm thick. Although FIG. 5A illustrates the III-nitride layer 515A being adjacent to the first doped semiconductor layer 510, the II-oxide layer 515B can be adjacent to the first doped semiconductor layer 510.

A second doped semiconductor layer 525 is arranged on the absorption layer 515. In the illustrated embodiment, the second doped semiconductor layer 525 is a p-type layer. The second doped semiconductor layer 525 can be, for example, between 5 and 500 nm thick, and in one embodiment is 50 nm thick. The second doped semiconductor layer 525 can be, for example, magnesium-doped p-type gallium nitride layer with a magnesium concentration between 1×10¹⁷ cm⁻³ and 1×10²⁰ cm⁻³, and in one embodiment is 3×10¹⁹ cm⁻³.

The first and second doped semiconductor layers 510 and 525 can be comprised of a III-nitride or II-oxide material, however, the first and second doped semiconductor layers 510 and 525 should have a bandgap that is larger than the bandgap of the absorption layer 515 so that the energy can pass through the first doped semiconductor layer 510 to be absorbed by the absorption layer 515.

The absorption layer 515 can have more than just one set of II-oxide and III-nitride layers. Specifically, as illustrated in FIG. 5B, the absorption layer 515 of the energy conversion device 500B can include a plurality of sets 520₁-520ₓ of II-oxide and III-nitride layers. The II-oxide layers should have the same material and can have the same or different compositions of this same material. Likewise, the III-nitride layers should have the same material and can have the same or different compositions of this same material. In an embodiment, the number of sets of II-oxide and III-nitride layers can be, for example, greater than ten sets. A second doped semiconductor layer 525 is arranged on the absorption layer 515. In the illustrated embodiment, the second doped semiconductor layer 525 is a p-type layer. Although FIG. 5B illustrates a III-nitride layer adjacent to the first doped semiconductor layer 510, a II-oxide layer can be adjacent to the first doped semiconductor layer 510. Similarly, although FIG. 5B illustrates a II-oxide layer adjacent to the second doped semiconductor layer 525, a III-nitride layer can be adjacent to the second doped semiconductor layer 525.

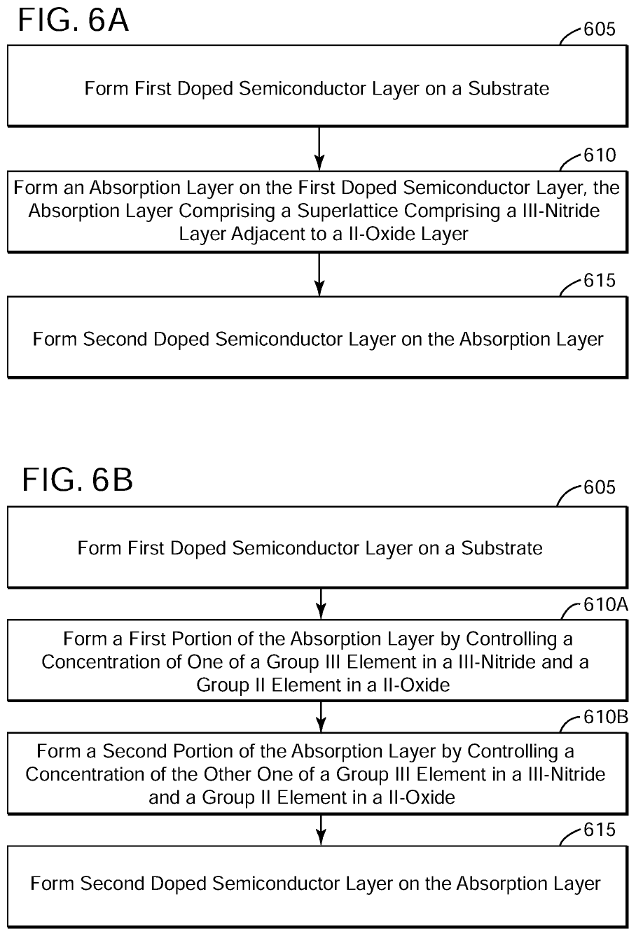

Methods of making the energy conversion device of FIGS. 5A and 5B are illustrated in FIGS. 6A and 6B. Initially, a first doped semiconductor layer 510 is formed on a substrate 505 (step 605). An absorption layer 515, comprising a superlattice of a III-nitride layer adjacent to a II-oxide layer, is then formed on the first doped semiconductor layer 510 (step 610). A second doped semiconductor layer 525 is formed on the absorption layer 515 (step 615).

As discussed above, the bandgap of the superlattice can be defined by controlling the composition of the II-oxide and III-nitride layers. Thus, as illustrated in the flowchart of FIG. 6B, the formation of the absorption layer can involve forming the II-oxide and III-nitride layers using particular compositions. Specifically, a first portion of the absorption layer 515 can be formed by controlling a concentration of one of a group III element in a III-nitride and a group II element in a II-oxide (step 610A) and a second portion of the absorption layer 515 can be formed by controlling the concentration of the other one of a group III element in a III-nitride layer and a group II element in a II-oxide layer (step 610B). The concentrations of these layers are defined by the values of x, y, and z for the III-nitride layer of AlₓIn_{y}Ga_{z}N and the values of x′, y′, and z′ for the II-oxide layer of Mg_{x′}Cd_{y′}Zn_{z′}O, where x+y+z=1 and x′+y′+z′=1. Finally, a second doped semiconductor layer 525 is formed on the absorption layer 515 (step 615).

The methods of FIGS. 6A and 6B can be performed using any number of techniques, including chemical vapor deposition, metal-organic vapor-phase epitaxy, etc.

Although the flowcharts of FIGS. 6A and 6B describe forming a superlattice of a single II-oxide layer and a single III-nitride layer, as discussed above, an energy conversion device 500A or 500B can include more than one set of these layers. In the case of more than one set of these layers, the method of FIG. 6A would involve forming these sets of layers. Similarly, in the case of more than one set of these layers, the method of FIG. 6B would include steps 610A and 610B repeated for each set of layers.

The discussion above refers to layers adjoining the absorption layer as being doped semiconductor layers. It should be recognized that the II-oxide and III-nitride layers of the absorption layer are not intentionally doped. However, as one skilled in the art will recognize, there is inevitably some unintentional doping due to impurities (i.e., carbon, oxygen, hydrogen, etc.) present during the formation process.

As discussed above, the superlattice of II-oxide and III-nitride layers is particularly advantageous because it allows for defining the bandgap of the absorption layer. An additional advantage is that II-oxide and III-nitride materials are very stable, which provides for a very long lifetime of the energy conversion device.

Although embodiments have been described above in connection with a photocatalyst and a solar cell, the present invention can be used with other types of devices, such as a photodetector.

The disclosed embodiments provide an energy conversion device having a superlattice absorption layer and method for forming such an energy conversion device. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. An energy conversion device, comprising:
a substrate;
a first doped semiconductor layer arranged on the substrate; and
an absorption layer arranged on the first doped semiconductor layer, wherein the absorption layer comprises a superlattice comprising a III-nitride layer adjacent to a II-oxide layer.

2. The energy conversion device of claim 1, wherein the energy conversion device is a photocatalyst.

3. The energy conversion device of claim 1, further comprising:
a second doped semiconductor layer arranged on the absorption layer, wherein the energy conversion device is a solar cell.

4. The energy conversion device of claim 1, wherein the absorption layer further comprises:
a plurality of sets of a III-nitride layer adjacent to a II-oxide layer.

5. The energy conversion device of claim 1, wherein the III-nitride layer comprises AlₓIn_{y}Ga_{z}N, wherein x+y+z=1.

6. The energy conversion device of claim 1, wherein the II-oxide layer comprises MgₓCd_{y}Zn_{z}O, wherein x+y+z=1.

7. The energy conversion device of claim 1, wherein a bandgap of the absorption layer is a difference between a conduction band of the II-oxide layer and a valence band of the III-nitride layer.

8. The energy conversion device of claim 1, wherein a bandgap of the absorption layer is less than a bandgap of both of the III-nitride and II-oxide layers.

9. The energy conversion device of claim 1, wherein the substrate comprises one of sapphire, silicon, silicon carbide, gallium oxide (Ga₂O₃), gallium nitride, and zinc oxide.

10. A method for forming an energy conversion device, the method comprising:
forming a first doped semiconductor layer on a substrate; and
forming an absorption layer on the first doped semiconductor layer, wherein the absorption layer comprises a superlattice comprising a III-nitride layer adjacent to a II-oxide layer.

11. The method of claim 10, further comprising:
forming a second doped semiconductor layer on the absorption layer.

12. The method of claim 10, wherein the formation of the absorption layer further comprises:
forming a plurality of sets of a III-nitride layer adjacent to a II-oxide layer.

13. The method of claim 10, wherein the III-nitride layer comprises AlₓIn_{y}Ga_{z}N, wherein x+y+z=1.

14. The method of claim 10, wherein the II-oxide layer comprises MgₓCd_{y}Zn_{z}O, wherein x+y+z=1.

15. The method of claim 10, wherein the method is performed using chemical vapor deposition or metal-organic vapor-phase epitaxy.

16. A method for forming an energy conversion device, the method comprising:
forming a first doped semiconductor layer on a substrate;
forming an absorption layer on the first doped semiconductor layer by
forming a first portion of the absorption layer by controlling a concentration of one of a group III element in a III-nitride and a group II element in a II-oxide; and
forming a second portion of the absorption layer by controlling a concentration of the other one of a group III element in a III-nitride and a group II element in a II-oxide;
wherein the concentration of the group III element in the III-nitride and the concentration of the group II element in the II-oxide define a bandgap of the absorption layer.

17. The method of claim 16, further comprising:
forming a second doped semiconductor layer on the absorption layer.

18. The method of claim 16, wherein the formation of the absorption layer further comprises:
forming a plurality of sets of a III-nitride layer adjacent to a II-oxide layer.

19. The method of claim 16, wherein the III-nitride layer comprises AlₓIn_{y}Ga_{z}N, wherein x+y+z=1.

20. The method of claim 16, wherein the II-oxide layer comprises MgₓCd_{y}Zn_{z}O, wherein x+y+z=1.
